(19) United States
(12) Patent Application Publication
(10) Pub. No.: US 2008/0219301 A1
(43) Pub. Date: Sep. 11, 2008

(54) Sweep Speed Compensation

(76) Inventors: Wolf Steffens, Herrenberg (DE); Ulrich Kallmann, Tuebingen (DE); Ralf Haeussler, Dresden (DE); Bernd Nebendahl, Ditzingen (DE); Thomas Jensen, Rorschach (CH); Emmerich Mueller, Aidlingen (DE)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 10/527,902

(22) PCT Filed: Sep. 13, 2002
(86) PCT No.: PCT/EP02/10286

§ 371 Date: Oct. 2, 2006

(51) Int. Cl. H01S 5/14; H01S 5/0687

(52) U.S. Cl. 372/20

(57) ABSTRACT

A method of manipulating a laser source, includes analyzing an optical signal generated by the laser source, evaluating on the basis of the analysis an actual indicator corresponding with an actual value of a tuning velocity of the laser source, comparing the actual indicator with a desired indicator corresponding with a desired value of the tuning velocity to detect a deviation of the actual value of the tuning velocity from the desired value of the tuning velocity, and compensating the deviation if any by manipulating at least one parameter influencing the signal of the laser source.

This is the National Stage of International Application No. PCT/EP2002/010286, filed 13 Sep. 2002.

### BACKGROUND OF THE INVENTION

The present invention relates to manipulating a laser source, in particular to manipulating an optical signal leaving the laser source, more particular to manipulating an optical signal leaving a tunable laser source (TLS) swept in frequency.

### SUMMARY OF THE INVENTION

It is an object of the invention to provide improved manipulation of a laser source. The object is solved by the independent claims.

When tuning or sweeping the frequency of a TLS it often happens that the tuning velocity of the TLS is not linear. An advantage of an embodiment of the present invention is the possibility of compensating such non-linearity in the sweeping velocity when sweeping the frequency of the TLS.

Another advantage of embodiments of the present invention is that it is possible to compensate jitter on a signal of a certain frequency of the TLS, i.e. small but fast oscillations of the signal of the TLS about the desired frequency. Since jitter can also be understood as a tuning velocity, although undesired, jitter can be compensated, also. This can be done for example by interferometrically analyzing the signal generated by the TLS. If any beat frequency, i.e. a frequency generated by an interferometer in which light is split and recombined again after propagating two different path length, can be detected in the superimposed signal of the interferometer then there is jitter, i.e. a small and fast but undesired tuning velocity, on the signal which can be compensated until there is no jitter on the signal any more, i.e. the tuning velocity is zero.

In an embodiment of the present invention the compensation is realized by measuring an actual value of an indicator of the sweeping velocity, preferably by using a frequency or wavelength reference unit (WRU), by comparing the measured value with a desired value, preferably by using a deviation detector, and by compensating a deviation when a deviation was detected, preferably by using a phase controller influencing the signal of the laser source. The indicator can also be the tuning velocity itself. The WRU can be embodied by any kind of appropriate wavemeter and preferably as disclosed in any one of the following patent applications: EP-A-1099943, EP-A-1221599, or EP-A-0875743, the teaching thereof shall be incorporated herein by reference.

Furthermore, it is advantageous to generate the desired value by an electrical signal generator which can be forced by an appropriate control unit to generate as an indicator of the desired tuning velocity a frequency corresponding to the desired tuning velocity. Advantageously, this frequency can then be compared with a frequency measured by an interferometric WRU and a possible detection of a deviation is then be used to influence the optical signal created by the TLS.

The TLS can be influenced by using a phase controller introduced into the path of the laser in the TLS. Preferably, the phase controller comprises a fast phase controller to react on fast but small deviations and a slow phase controller to react on slow but large deviations. The fast phase controller can comprise an electro-optical modulator (EOM). The slow phase controller can comprise an actuator, which can comprise a piezo-electric element.

Possible application fields of embodiments of the present invention are measurement setups for measuring an optical property of a device under test using a TLS.

Other preferred embodiments are shown by the dependent claims.

It is clear that the invention can be partly embodied or supported by one or more suitable software programs, which can be stored on or otherwise provided by any kind of data carrier, and which might be executed in or by any suitable data processing unit.

### BRIEF DESCRIPTION OF THE DRAWINGS

Other objects and many of the attendant advantages of the present invention will be readily appreciated and become better understood by reference to the following detailed description when considering in connection with the accompanied drawings. The components in the drawings are not necessarily to scale, emphasis instead being placed upon clearly illustrating the principles of the present invention. Features that are substantially or functionally equal or similar will be referred to with the same reference sign(s).

FIGS. 1 and 2 show schematic illustrations of embodiments of the present invention.

### DETAILED DESCRIPTION PREFERRED EMBODIMENTS OF THE INVENTION

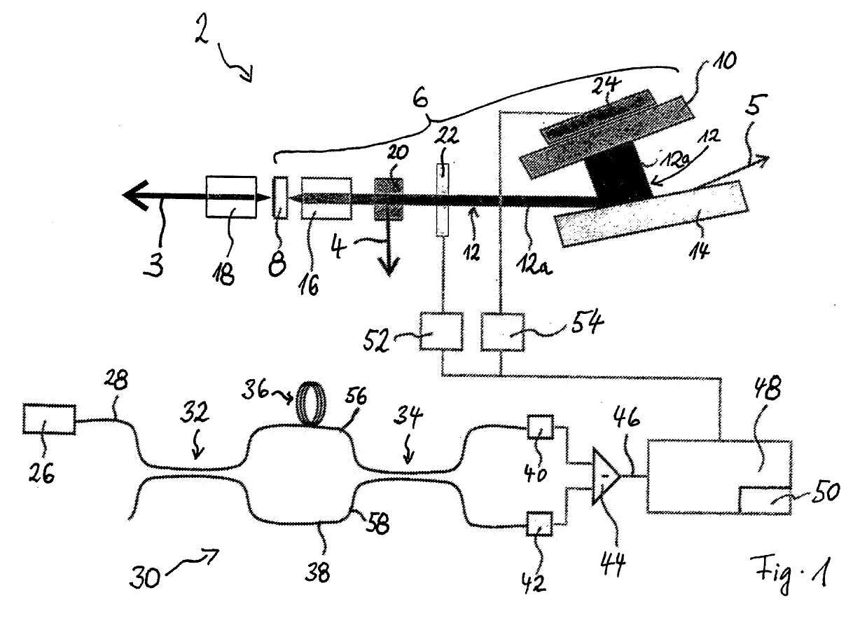

Referring now in greater detail to the drawings, FIG. 1 shows a schematic illustration of an apparatus for compensating a deviation of an optical signal compared to a desired value, e.g. for compensating a non-linearity in a sweeping velocity of a TLS 2, according to an embodiment of the present invention.

In the specific embodiment of the TLS 2 as shown herein, the TLS 2 provides as output at least one of laser beams 3, 4, 5 and comprises a laser cavity 6. The laser cavity 6 comprises a lasing chip 8 and a cavity end element 10 providing a path 12 for the laser beam 12a within the cavity 6. In the path 12 there is introduced a movable tuning element 14 to tune the TLS 2. In this embodiment the TLS 2 is tuned with a tuning velocity of e.g. 100 GHz/s. A lens 16 in the path 12 adjacent to the chip 8 is provided to focus the laser beam 12a onto the chip 8. A lens 18 adjacent to the chip 8 opposite to the lens 16 is provided to focus the resulting laser beam 3 of the TLS 2. A beam splitter 20 in the path 12 adjacent to the lens 16 is provided to provide the resulting laser beam 4 of the TLS 2.

Any other type of TLS as the specific embodiment of TLS 2 can be applied accordingly, as will be shown in the following.

An EOM 22 as a fast phase controller (FPC) in the path 12 adjacent to the beam splitter 20 is provided as a fast phase control of the resulting beams 3, 4, 5 of the TLS 2. A piezo electric element 24 as a slow phase controller (SPC) in contact with the cavity end element 10 provides a slow phase control of the resulting beams 3, 4, 5 of the TLS 2. How to control the FPC 22 and the SPC 24 will be described below.

A part of beam 3 is provided to a connector 26. Alternatively, beams 3-5 or parts of the other beams 4 and 5 or any other combination of beams 3-5 can be provided to the connector 26. The connector 26 provides beam 3 to a fiber 28. Fiber 28 is part of an interferometer 30 comprising two two-port couplers 32 and 34, a delay loop 36, a second fiber 38 and detectors 40 and 42 to detect the power of the light emitted by fibers 28 and 38. Alternatively, not shown three-port couplers can be used instead of the two-port couplers 32 and 34. Moreover, all kinds of interferometers can be used for the purpose of the present invention, e.g. Michelson-, Mach-Zehnder-, Fabry-Perot-, or Fizeau-interferometers.

A subtractor 44 is connected to the detectors 40 and 42 to subtract the signals detected by the detectors 40 and 42 from each other to provide a resulting signal 46. Resulting signal 46 is provided to a frequency deviation detection unit (FDDU) 48 comprising a memory 50 to store a dependency of the detected frequency detected by detectors 40 and 42 on the tuning velocity of TLS 2. FDDU 48 controls via a high pass filter (HP) 52 with the FPC 22 and via a low pass filter (LP) 54 with the SPC 24.

An inventive method according to the shown embodiment works as follows:

When tuning the TLS 2 it is generated a laser beam 3 with increasing optical frequency. A part of laser beam 3, e.g. 5% of beam 3, is coupled to connector 26. Coupler 32 splits the signal of fiber 28 into two parts 56 and 58. These parts 56 and 58 interfere at coupler 34 and generate a signal of a certain frequency, which is an indicator or measure of the tuning rate of the TLS 2. Detector 40 detects a signal having this frequency. Detector 42 detects a signal having the same frequency. These two signals are subtracted by a subtractor 44 to provide signal 46 to the FDDU 48 again having the same but amplitude shifted frequency. FDDU compares the frequency of signal 46 with the frequency stored in memory 50 for the above mentioned tuning velocity of TLS 2. When FDDU 48 detects a deviation of the tuning velocity from the desired above mentioned tuning velocity it provides appropriate control signals to FPC 22 and to SPC 24 to compensate for the deviation until there is no deviation anymore, i.e. the measured tuning velocity is equal to the desired tuning velocity.

According to the above described method it is also possible to compensate jitter on beams 3-5 of TLS 2.

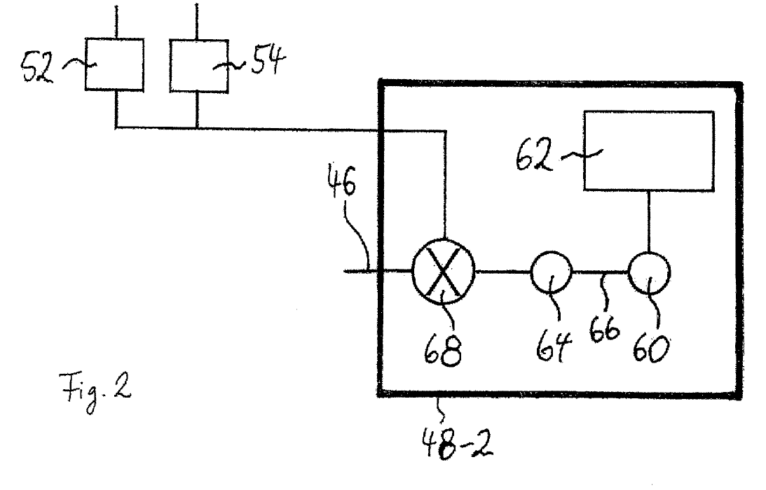

FIG. 2 shows a schematic illustration of a preferred embodiment 48-2 of the FDDU 48. The FDDU 48-2 comprises an electrical signal generator 60 forced by a control unit 62 to generate a desired frequency 66 corresponding to the desired tuning velocity. The desired frequency 66 is phase shifted by a phase shifter 64 to implement a fixed phase relation between the desired frequency 66 and the measured frequency 46 and then desired frequency 66 is compared with the measured frequency 46 measured by the interferometric WRU 30 by mixing the desired frequency 66 and the measured frequency 46 with a mixer 68. A possible detection of a deviation is then be used to influence the TLS 2 according to the above described method.

1. A method of manipulating a laser source, comprising the steps of:
analyzing an optical signal generated by the laser source,
evaluating on the basis of the analysis an actual indicator corresponding with an actual value of a tuning velocity of the laser source,
comparing the actual indicator with a desired indicator corresponding with a desired value of the tuning velocity to detect a deviation of the actual value of the tuning velocity from the desired value of the tuning velocity, and
compensating the deviation, if any, by manipulating at least one parameter influencing the signal of the laser source.

2. The method of claim 1, wherein the step of analyzing the optical signal comprises the steps of:
letting a first part of the signal interfere with a second part of the signal resulting in a superimposed signal, with the first part being delayed with respect to the second part, and
detecting the power of the superimposed signal.

3. The method of claim 2, further comprising the steps of:
evaluating the actual indicator by:
measuring as the actual indicator a frequency of oscillations of the detected power.

4. The method of claim 3, further comprising at least one of the steps of:
supplying the desired indicator by using a stored dependency of frequency of oscillations of a detected power of the signal on tuning velocity;
supplying the desired indicator by generating as the desired indicator a frequency corresponding to the desired tuning velocity;
comparing the actual indicator with a desired indicator by mixing the actual indicator with the desired indicator.

5.-6. (canceled)

7. The method of claim 1, further comprising at least one of the steps of:
tuning the optical signal in wavelength with a tuning velocity greater than zero;
compensating the deviation if any by manipulating as a parameter a length of a cavity of the laser source;
compensating a fast deviation, if any, by electro-optically changing an optical path length of the cavity;
compensating a slow deviation if any by mechanically changing an optical path length of the cavity.

8.-9. (canceled)

10. A software program or product, preferably stored on a data carrier, for executing the method of:
analyzing an optical signal generated by the laser source,
evaluating on the basis of the analysis an actual indicator corresponding with an actual value of a tuning velocity of the laser source,
comparing the actual indicator with a desired indicator corresponding with a desired value of the tuning velocity to detect a deviation of the actual value of the tuning velocity from the desired value of the tuning velocity, and
compensating the deviation, if any, by manipulating at least one parameter influencing the signal of the laser source,
when run on a data processing system such as a computer.

11. An apparatus for manipulating a laser source, comprising:
an analyzer for analyzing an optical signal generated by the laser source, evaluating on the basis of the analysis an actual indicator corresponding with an actual value of a tuning velocity of the laser source, and comparing the actual indicator with a desired indicator corresponding with a desired value of the tuning velocity to detect a deviation of the actual value of the tuning velocity from the desired value of the tuning velocity, and
a compensator connected to the analyzer for compensating the deviation if any by manipulating at least one parameter influencing the signal of the laser source.

12. The apparatus of claim 11, wherein the analyzer further comprises at least one of the features:
an interferometer for letting a first part of the signal interfere with a second part of the signal resulting in a superimposed signal, with the first part being delayed with respect to the second part, and a detector for detecting the power of the superimposed signal;
a frequency deviation detection unit connected to the detector for measuring as the actual indicator a frequency of oscillations of the detected power;
a memory for storing and supplying a dependency of frequency of oscillations of a detected power of the signal on tuning velocity to supply the desired indicator to the analyzer;
an electrical signal generator for supplying the desired indicator to the analyzer by generating as the desired indicator a frequency corresponding to the desired tuning velocity;
a mixer for comparing the actual indicator with a desired indicator by mixing the actual indicator with the desired indicator.

13.-16. (canceled)

17. The apparatus of claim 11,
wherein the compensator further comprises:
a manipulator for manipulating as a parameter a length of a cavity of the laser source, the manipulator being controlled by the analyzer.

18. The apparatus of claim 17, wherein
the manipulator further comprises:
an electro-optical modulator in the path of the beam in the cavity for compensating a fast deviation if any by electro-optically changing an optical path length of the cavity.

19. The apparatus of claim 17, further comprising:
a piezo-electric element acting on an cavity end element of the cavity for compensating a slow deviation if any by mechanically changing an optical path length of the cavity.
